(19) United States
(12) Patent Application Publication
(10) Pub. No.: US 2013/0240351 A1
(43) Pub. Date: Sep. 19, 2013

(54) SPUTTERING TARGETS AND ASSOCIATED SPUTTERING METHODS FOR FORMING HERMETIC BARRIER LAYERS

(71) Applicant: Corning Incorporated, Corning, NY (US)

(72) Inventors: Bruce Gardiner Aitken, Corning, NY (US); Shari Elizabeth Koval, Beaver Dams, NY (US); Mark Alejandro Quesada, Horseheads, NY (US)

(21) Appl. No.: 13/799,611

(22) Filed: Mar. 13, 2013

Related U.S. Application Data
(60) Provisional application No. 61/610,695, filed on Mar. 14, 2012.

(51) Int. Cl. C23C 14/10

(52) U.S. Cl. CPC C23C 14/10
USPC 204/298.13; 65/66; 427/314; 264/109

(57) ABSTRACT

A sputtering target comprises a low T_{g} glass or an oxide of copper or tin. Such target materials can be used to form mechanically-stable thin films that exhibit a self-passivating phenomenon and which can be used to seal sensitive workpieces from exposure to air or moisture. Low T_{g} glass materials may include phosphate glasses such as tin phosphates and tin fluorophosphates, borate glasses, tellurite glasses and chalcogenide glasses, as well as combinations thereof.

### CROSS-REFERENCE TO RELATED APPLICATIONS

This application claims the benefit of priority under 35 U.S.C. §119 of U.S. Provisional Application Ser. No. 61/610,695 filed on Mar. 14, 2012, the content of which is relied upon and incorporated herein by reference in its entirety.

### BACKGROUND

The present disclosure relates generally to hermetic barrier layers, and more specifically to sputtering target compositions and sputtering methods for forming hermetic barrier layers.

Hermetic barrier layers can be used to protect sensitive materials from deleterious exposure to a wide variety of liquids and gases. As used herein, “hermetic” refers to a state of being completely or substantially sealed, especially against the escape or entry of water or air, though protection from exposure to other liquids and gases is contemplated.

Approaches to creating hermetic barrier layers include physical vapor deposition (PVD) methods such as evaporation or sputtering, and chemical vapor deposition (CVD) methods such as plasma-enhanced CVD (PECVD). Using such methods, a hermetic barrier layer can be formed directly over the device or material to be protected. Alternatively, hermetic barrier layers can be formed on an intermediate structure such as a substrate or a gasket, which can cooperate with an additional structure to provide a hermetically-sealed workpiece.

Both reactive and non-reactive sputtering can be used to form a hermetic barrier layer, for instance, under room temperature or elevated temperature deposition conditions. Reactive sputtering is performed in conjunction with a reactive gas such as oxygen or nitrogen, which results in the formation of a corresponding compound barrier layer (i.e., oxide or nitride). Non-reactive sputtering can be performed using an oxide or nitride target having a desired composition in order to form a barrier layer having a similar or related composition.

On the one hand, reactive sputtering processes typically exhibit faster deposition rates than non-reactive processes, and thus may possess an economic advantage in certain methods. However, although increased throughput can be achieved via reactive sputtering, its inherently reactive nature may render such processes incompatible with sensitive devices or materials that require protection.

Economical sputtering materials, including sputtering targets that can be used to protect sensitive workpieces such as devices, articles or raw materials from undesired exposure to oxygen, water, heat or other contaminants are highly desirable.

### SUMMARY

Sputtering targets comprise low T_{g} glass materials, precursors of a low T_{g} glass materials, or an oxide of copper or tin. The copper or tin oxide material may be polycrystalline or amorphous. Example low T_{g} glass materials include phosphate glasses, borate glasses, tellurite glasses and chalcogenide glasses.

A method of forming a sputtering target comprising a low T_{g} glass material comprises providing a mixture of raw material powders, heating the powder mixture to form a molten low T_{g} glass, and shaping the glass melt into a solid sputtering target.

A further method of forming a pressed powder sputtering target comprises providing a mixture of raw material powders, and pressing the mixture into a solid sputtering target, where the powder mixture comprises CuO, SnO or a low T_{g} glass precursor composition selected from the group consisting of a phosphate glass, a borate glass, a tellurite glass, and a chalcogenide glass.

Additional features and advantages will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention and together with the description serve to explain the principles and operations of the invention.

### BRIEF DESCRIPTION OF THE DRAWINGS

FIG. 1 is a schematic diagram of a single chamber sputter tool for forming hermetic barrier layers;

FIG. 2 is an illustration of a hermetic barrier layer formed over a surface of a substrate;

FIG. 3 depicts a portion of an RF sputtering apparatus according to an example embodiment;

FIG. 4 depicts a portion of a continuous in-line magnetron sputtering apparatus according to a further example embodiment;

FIG. 5 in an illustration of a calcium-patch test sample for accelerated evaluation of hermeticity;

FIG. 6 shows test results for non-hermetically sealed (left) and hermetically sealed (right) calcium patches following accelerated testing;

FIG. 7 shows glancing angle (A,C) and thin film (B,D) x-ray diffraction (XRD) spectra for a hermetic CuO-based barrier layer-forming material (top series) and a non-hermetic Cu₂O-based barrier layer forming material (bottom series);

FIGS. 8A-8I show a series of glancing angle XRD spectra for hermetic CuO-based barrier layers following accelerated testing;

FIG. 9 is a series of glancing angle XRD spectra for hermetic SnO-based barrier layers (top) and non-hermetic SnO₂-based barrier layers (bottom) following accelerated testing;

FIG. 10 is a photograph of a copper backing plate according to various embodiments;

FIG. 11 is a photograph of a solder-coated copper backing plate;

FIG. 12 is an image of an example sputtering target comprising an annealed low T_{g} glass material;

FIG. 13 in an image of a pressed low T_{g} glass sputtering target;

FIG. 14 shows a large form factor sputtering target prior to compressing;

FIG. 15 shows a circular copper backing plate with loose powder material incorporated into a central area of the plate; and

FIG. 16 shows the circular copper backing plate of FIG. 15 after compression of the loose powder.

### DETAILED DESCRIPTION

Mechanically-stable hermetic barrier layers can be formed by physical vapor deposition (e.g., sputter deposition or laser ablation) of a suitable starting material directly onto a workpiece or onto a substrate that can be used to encapsulate a workpiece. The starting materials include low T_{g} glass materials and their precursors, and polycrystalline or amorphous oxides of copper or tin. As defined herein, a low T_{g} glass material has a glass transition temperature of less than 400° C., e.g., less than 350, 300, 250 or 200° C.

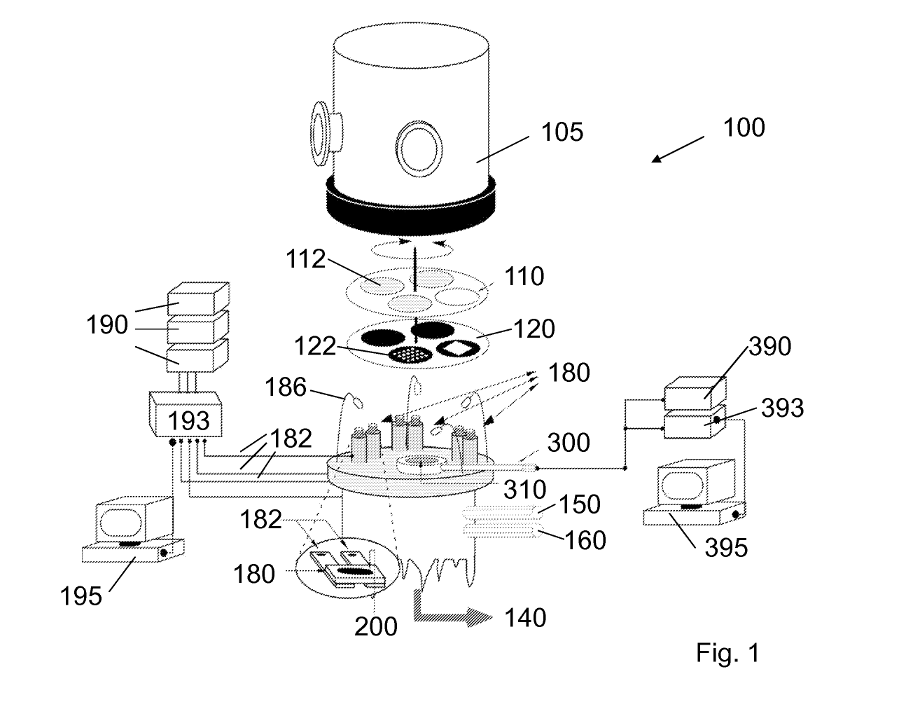

A single-chamber sputter deposition apparatus 100 for forming such barrier layers is illustrated schematically in FIG. 1. While the apparatus and attendant methods are described below with respect to deposition onto a substrate, it will be appreciated that the substrate may be replaced by a workpiece or other device that is to be protected.

The apparatus 100 includes a vacuum chamber 105 having a substrate stage 110 onto which one or more substrates 112 can be mounted, and a mask stage 120, which can be used to mount shadow masks 122 for patterned deposition of different layers onto the substrates. The chamber 105 is equipped with a vacuum port 140 for controlling the interior pressure, as well as a water cooling port 150 and a gas inlet port 160. The vacuum chamber can be cryo-pumped (CTI-8200/Helix; MA, USA) and is capable of operating at pressures suitable for both evaporation processes (˜10⁻⁶ Torr) and RF sputter deposition processes (˜10⁻³ Torr).

As shown in FIG. 1, multiple evaporation fixtures 180, each having an optional corresponding shadow mask 122 for evaporating material onto a substrate 112, are connected via conductive leads 182 to a respective power supply 190. A target material 200 to be evaporated can be placed into each fixture 180. Thickness monitors 186 can be integrated into a feedback control loop including a controller 193 and a control station 195 in order to affect control of the amount of material deposited.

In an example system, each of the evaporation fixtures 180 are outfitted with a pair of copper leads 182 to provide DC current at an operational power of about 80-180 Watts. The effective fixture resistance will generally be a function of its geometry, which will determine the precise current and wattage.

An RF sputter gun 300 having a sputtering target 310 is also provided for forming a barrier layer on a substrate. The RF sputter gun 300 is connected to a control station 395 via an RF power supply 390 and feedback controller 393. For sputtering inorganic, hermetic layers, water-cooled cylindrical RF sputtering guns (Onyx-3™, Angstrom Sciences, Pa) can be positioned within the chamber 105. Suitable RF deposition conditions include 50-150 W forward power (<1 W reflected power), which corresponds to a typical deposition rate of about ˜5 Å/second (Advanced Energy, Co, USA).

During deposition of the hermetic barrier layers, the substrate may optionally be cooled or heated to a desired temperature (e.g., −30° C.-150° C.). In embodiments, the substrate is held at about room temperature. A post-deposition sintering or annealing step of the as-deposited material may be performed or omitted.

The hermetic barrier layers disclosed herein may be characterized as thin film materials. A total thickness of a hermetic barrier layer can range from about 150 nm to 200 microns. In various embodiments, a thickness of the as-deposited layer can be less than 200 microns, e.g., less than 200, 100, 50, 20, 10, 5, 2, 1, 0.5 or 0.2 microns. Example thicknesses of as-deposited glass layers include 200, 100, 50, 20, 10, 5, 2, 1, 0.5, 0.2 or 0.15 microns.

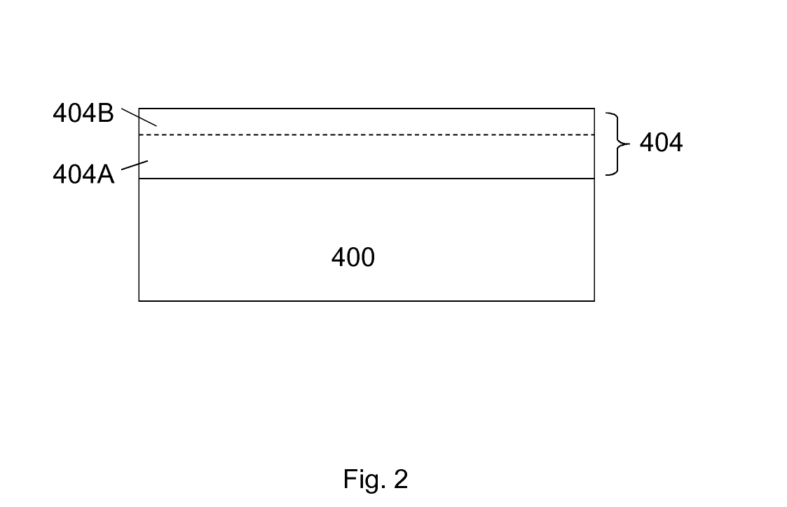

According to various sputtering approaches, a self-passivating layer can be formed on a surface of a substrate or workpiece from a suitable target material. The self-passivating layer is an inorganic material. Without wishing to be bound by theory, it is believed that, according to various embodiments, during or after its formation, the as-deposited layer reacts with moisture or oxygen to form a mechanically-stable hermetic barrier layer. The hermetic barrier layer comprises the as-deposited layer and a second inorganic layer, which is the reaction product of the deposited layer with moisture or oxygen. Thus, the second inorganic layer forms at the ambient interface of the as-deposited layer. A schematic of a hermetic barrier layer 404 formed over a surface of a substrate 400 is illustrated in FIG. 2. In the illustrated embodiment, the hermetic barrier layer 404 comprises a first (as-deposited) inorganic layer 404A, and a second (reaction product) inorganic layer 404B. In embodiments, the first and second layers can cooperate to form a composite thin film that can isolate and protect an underlying structure. The passivatable as-deposited layer comprises a low T_{g} glass material or an oxide of copper or tin.

According to further embodiments, a molar volume of the second inorganic layer is from about −1% to 15% greater than a molar volume of the first inorganic layer, and an equilibrium thickness of the second inorganic layer is at least 10% of but less than an initial thickness of the first inorganic layer. While the first inorganic layer can be amorphous, the second inorganic layer can be at least partially crystalline.

In embodiments, the molar volume change (e.g., increase) manifests as a compressive force within the composite barrier layer that contributes to a self-sealing phenomenon. Because the second layer is formed as the spontaneous reaction product of the first inorganic layer with oxygen or water, as-deposited layers (first inorganic layers) that successfully form hermetic barrier layers are less thermodynamically stable than their corresponding second inorganic layers. Thermodynamic stability is reflected in the respective Gibbs free energies of formation.

Sputter-deposited hermetic barrier layers according to the present disclosure may exhibit a self-passivating attribute that efficiently and significantly impedes moisture and oxygen diffusion.

According to embodiments, the choice of the hermetic barrier layer material(s) and the processing conditions for forming hermetic barrier layers over a workpiece or substrate are sufficiently flexible that the workpiece or substrate is not adversely affected by formation of the barrier layer.

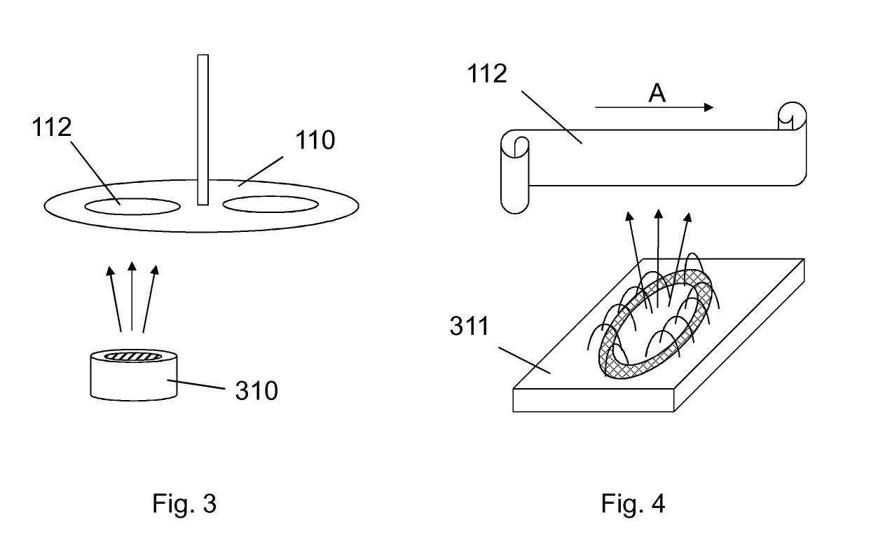

Example sputtering configurations according to various embodiments are illustrated in FIGS. 3 and 4. FIG. 3 shows RF sputtering from a sputtering target 310 to form a barrier layer on a substrate 112 that is supported by a rotating substrate stage 110 as also depicted in FIG. 1. FIG. 4 shows a portion of an in-line planar magnetron sputtering apparatus configured to continuously form a hermetic barrier layer on a surface of a translating substrate. A direction of motion of the substrate is shown in FIG. 4 by arrow A. The pristine substrate can be unwrapped from a first roll, passed over a deposition zone of the magnetron sputtering target 311 to provide a barrier layer on a portion of the workpiece, and then the coated workpiece can be wrapped onto a second roll.

In general, suitable materials for forming hermetic barrier layers include low T_{g} glasses and suitably reactive oxides of copper or tin. Hermetic barrier layers can be formed from low T_{g} materials such as phosphate glasses, borate glasses, tellurite glasses and chalcogenide glasses. Example borate and phosphate glasses include tin phosphates, tin fluorophosphates and tin fluoroborates. Sputtering targets can include such glass materials or, alternatively, precursors thereof. Example copper and tin oxides are CuO and SnO, which can be formed from sputtering targets comprising pressed powders of these materials.

Optionally, the compositions can include one or more dopants, including but not limited to tungsten, cerium and niobium. Such dopants, if included, can affect, for example, the optical properties of the barrier layer, and can be used to control the absorption by the barrier material of electromagnetic radiation, including laser radiation. For instance, doping with ceria can increase the absorption by a low T_{g} glass barrier at laser processing wavelengths, which can enable the use of laser-based sealing techniques after formation on a substrate or gasket.

Example tin fluorophosphate glass compositions can be expressed in terms of the respective compositions of SnO, SnF₂ and P₂O₅ in a corresponding ternary phase diagram. Suitable tin fluorophosphates glasses include 20-100 mol % SnO, 0-50 mol % SnF₂ and 0-30 mol % P₂O₅. These tin fluorophosphates glass compositions can optionally include 0-10 mol % WO₃, 0-10 mol % CeO₂ and/or 0-5 mol % Nb₂O₅.

For example, a composition of a doped tin fluorophosphate starting material suitable for forming a hermetic barrier layer comprises 35 to 50 mole percent SnO, 30 to 40 mole percent SnF₂, 15 to 25 mole percent P₂O₅, and 1.5 to 3 mole percent of a dopant oxide such as WO₃, CeO₂ and/or Nb₂O₅.

A tin fluorophosphate glass composition according to one particular embodiment is a niobium-doped tin oxide/tin fluorophosphate/phosphorus pentoxide glass comprising about 38.7 mol % SnO, 39.6 mol % SnF₂, 19.9 mol % P₂O₅ and 1.8 mol % Nb₂O₅. Sputtering targets that can be used to form such a glass layer may include, expressed in terms of atomic mole percent, 23.04% Sn, 15.36% F, 12.16% P, 48.38% 0 and 1.06% Nb.

A tin phosphate glass composition according to an alternate embodiment comprises about 27% Sn, 13% P and 60% 0, which can be derived from a sputtering target comprising, in atomic mole percent, about 27% Sn, 13% P and 60% 0. As will be appreciated, the various glass compositions disclosed herein may refer to the composition of the deposited layer or to the composition of the source sputtering target.

As with the tin fluorophosphates glass compositions, example tin fluoroborate glass compositions can be expressed in terms of the respective ternary phase diagram compositions of SnO, SnF₂ and B₂O₃. Suitable tin fluoroborate glass compositions include 20-100 mol % SnO, 0-50 mol % SnF₂ and 0-30 mol % B₂O₃. These tin fluoroborate glass compositions can optionally include 0-10 mol % WO₃, 0-10 mol % CeO₂ and/or 0-5 mol % Nb₂O₅.

Additional aspects of suitable low T_{g} glass compositions and methods used to form glass layers from these materials are disclosed in commonly-assigned U.S. Pat. No. 5,089,446 and U.S. patent application Ser. Nos. 11/207,691, 11/544,262, 11/820,855, 12/072,784, 12/362,063, 12/763,541 and 12/879,578, the entire contents of which are incorporated by reference herein.

The hermetic barrier layer materials disclosed herein may comprise a binary, ternary or higher-order composition. A survey of several binary oxide systems reveals other materials capable of forming self-passivating hermetic barrier layers. In the copper oxide system, for example, as-deposited amorphous CuO reacts with moisture/oxygen to partially form crystalline Cu₄O₃ and the resulting composite layer exhibits good hermeticity. When Cu₂O is deposited as the first inorganic layer, however, the resulting film is not hermetic. In the tin oxide system, as-deposited amorphous SnO reacts with moisture/oxygen to partially form crystalline Sn₆O₄(OH)₄ and SnO₂. The resulting composite layer exhibits good hermeticity. When SnO₂ is deposited as the first inorganic layer, however, the resulting film is not hermetic.

A hermetic layer is a layer which, for practical purposes, is considered substantially airtight and substantially impervious to moisture. By way of example, the hermetic thin film can be configured to limit the transpiration (diffusion) of oxygen to less than about 10⁻² cm³/m²/day (e.g., less than about 10⁻³ cm³/m²/day), and limit the transpiration (diffusion) of water to about 10⁻² g/m²/day (e.g., less than about 10⁻³, 10⁻⁴, 10⁻⁵ or 10⁻⁶ g/m²/day). In embodiments, the hermetic thin film substantially inhibits air and water from contacting an underlying workpiece or a workpiece sealed within a structure using the hermetic material.

To evaluate the hermeticity of the hermetic barrier layers, calcium patch test samples were prepared using the single-chamber sputter deposition apparatus 100. In a first step, calcium shot (Stock #10127; Alfa Aesar) was evaporated through a shadow mask 122 to form 25 calcium dots (0.25 inch diameter, 100 nm thick) distributed in a 5×5 array on a 2.5 inch square glass substrate. For calcium evaporation, the chamber pressure was reduced to about 10 Torr. During an initial pre-soak step, power to the evaporation fixtures 180 was controlled at about 20 W for approximately 10 minutes, followed by a deposition step where the power was increased to 80-125 W to deposit about 100 nm thick calcium patterns on each substrate.

Following evaporation of the calcium, the patterned calcium patches were encapsulated using comparative inorganic oxide materials as well as hermetic inorganic oxide materials according to various embodiments. The inorganic oxide materials were deposited using room temperature RF sputtering of pressed powder or glass sputtering targets. The pressed powder targets were prepared separately using a manual heated bench-top hydraulic press (Carver Press, Model 4386, Wabash, Ind., USA). The press was typically operated at 5,000 psi for 2 hours at about 200° C.

The RF power supply 390 and feedback control 393 (Advanced Energy, Co, USA) were used to form first inorganic oxide layers over the calcium having a thickness of about 2 micrometers. No post-deposition heat treatment was used. Chamber pressure during RF sputtering was about 1 milliTorr. The formation of a second inorganic layer over the first inorganic layer was initiated by ambient exposure of the test samples to room temperature and atmospheric pressure prior to testing.

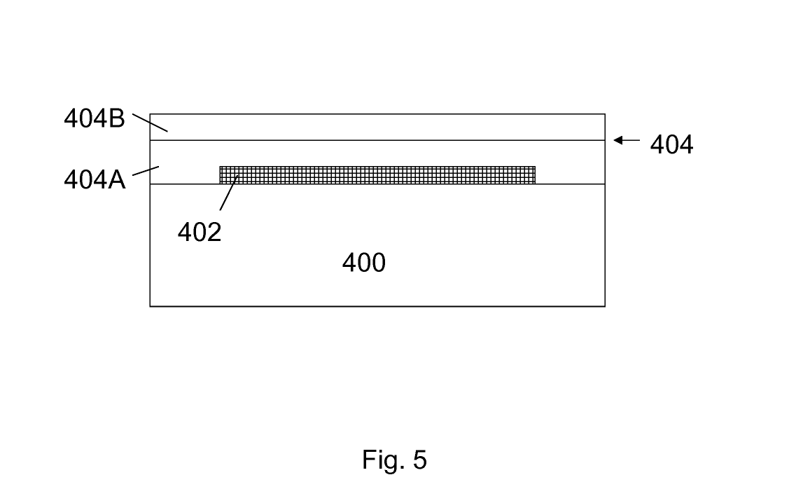

FIG. 5 is a cross-sectional view of a test sample comprising a glass substrate 400, a patterned calcium patch (˜100 nm) 402, and an inorganic oxide film (˜2 μm) 404. Following ambient exposure, the inorganic oxide film 404 comprises a first inorganic layer 404A and a second inorganic layer 404B. In order to evaluate the hermeticity of the inorganic oxide film, calcium patch test samples were placed into an oven and subjected to accelerated environmental aging at a fixed temperature and humidity, typically 85° C. and 85% relative humidity (“85/85 testing”).

The hermeticity test optically monitors the appearance of the vacuum-deposited calcium layers. As-deposited, each calcium patch has a highly reflective metallic appearance. Upon exposure to water and/or oxygen, the calcium reacts and the reaction product is opaque, white and flaky. Survival of the calcium patch in the 85/85 oven over 1000 hours is equivalent to the encapsulated film surviving 5-10 years of ambient operation. The detection limit of the test is approximately 10⁷ g/m² per day at 60° C. and 90% relative humidity.

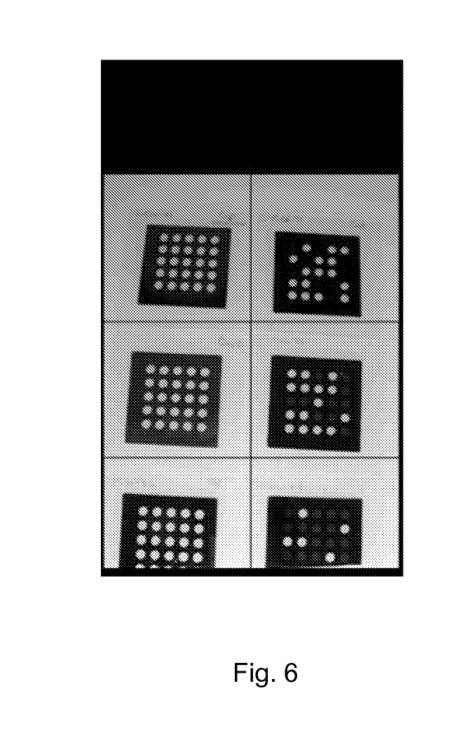

FIG. 6 illustrates behavior typical of non-hermetically sealed and hermetically sealed calcium patches after exposure to the 85/85 accelerated aging test. In FIG. 6, the left column shows non-hermetic encapsulation behavior for Cu₂O films formed directly over the patches. All of the Cu₂O-coated samples failed the accelerated testing, with catastrophic delamination of the calcium dot patches evidencing moisture penetration through the Cu₂O layer. The right column shows positive test results for nearly 50% of the samples comprising a CuO-deposited hermetic layer. In the right column of samples, the metallic finish of 34 intact calcium dots (out of 75 test samples) is evident.

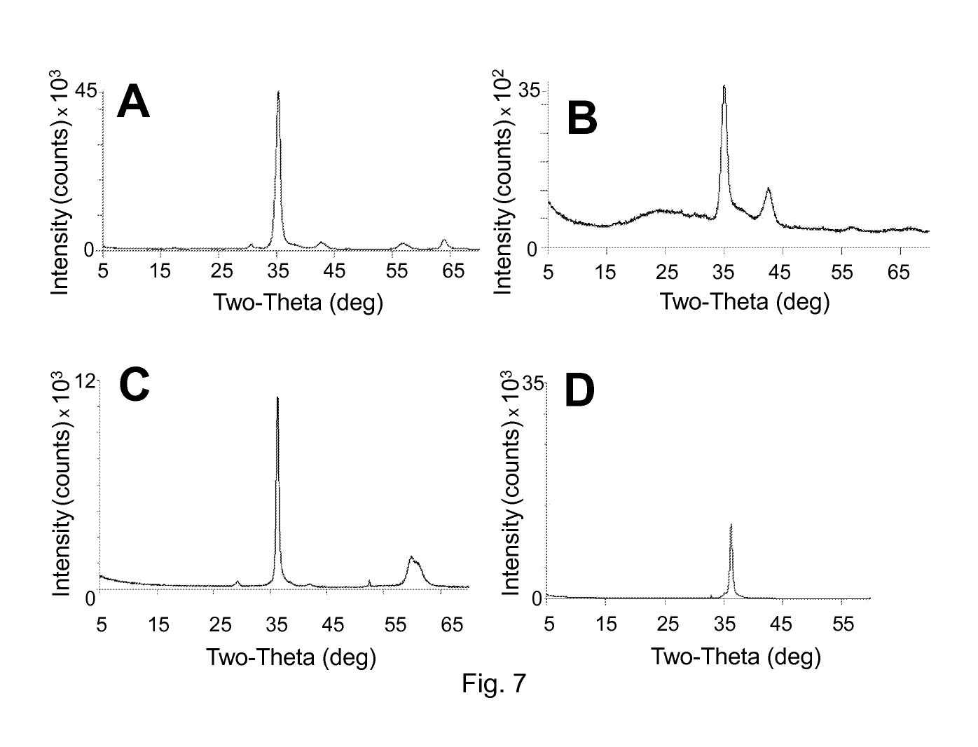

Both glancing angle x-ray diffraction (GIXRD) and traditional powder x-ray diffraction were used to evaluate the near surface and entire oxide layer, respectively, for both non-hermetic and hermetic deposited layers. FIG. 7 shows GIXRD data (plots A and C) and traditional powder reflections (plots B and D) for both hermetic CuO-deposited layers (plots A and B) and non-hermetic Cu₂O-deposited layers (plots C and D). Typically, the 1 degree glancing angle used to generate the GIXRD scans of FIGS. 4A and 4C probes a near-surface depth of approximately 50-300 nanometers.

Referring still to FIG. 7, the hermetic CuO-deposited film (plot A) exhibits near surface reflections that index to the phase paramelaconite (Cu₄O₃), though the interior of the deposited film (plot B) exhibits reflections consistent with a significant amorphous copper oxide content. The paramelaconite layer corresponds to the second inorganic layer, which formed from the first inorganic layer (CuO) that was formed directly over the calcium patches. In contrast, the non-hermetic Cu₂O-deposited layer exhibits x-ray reflections in both scans consistent with Cu₂O.

The XRD results suggest that hermetic films exhibit a significant and cooperative reaction of the sputtered (as-deposited) material with heated moisture in the near surface region only, while non-hermetic films react with heated moisture in their entirety yielding significant diffusion channels which preclude effective hermeticity. For the copper oxide system, the hermetic film data (deposited CuO) suggest that paramelaconite crystallite layer forms atop an amorphous base of un-reacted sputtered CuO, thus forming a mechanically stable and hermetic composite layer.

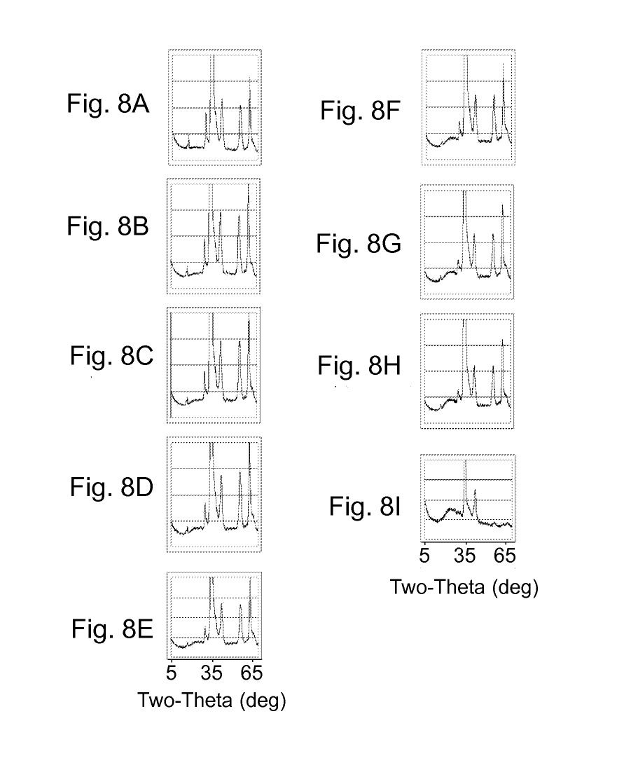

FIGS. 8A-8H show a series of GIXRD plots, and FIG. 81 shows a Bragg XRD spectrum for a CuO-deposited hermetic barrier layers following accelerated testing. Bragg diffraction from the entire film volume has an amorphous character, with the paramelaconite phase present at/near the film's surface. Using a CuO density of 6.31 g/cm³, a mass attenuation coefficient of 44.65 cm²/g, and an attenuation coefficient of 281.761 cm⁻¹, the paramelaconite depth was estimated from the GIXRD plots of FIG. 8. In FIGS. 8A-8H, successive glancing incident x-ray diffraction spectra obtained at respective incident angles of 1°, 1.5°, 2°, 2.5°, 3.0°, 3.5°, 4°, and 4.5° show a surface layer (paramelaconite) that comprises between 31% (619 nm) and 46% (929 nm) of the original 2 microns of sputtered CuO after exposure to 85° C. and 85% relative humidity for 1092 hours. A summary of the calculated surface depth (probed depth) for each GIXRD angle is shown in Table 1.

TABLE 1
Paramelaconite depth profile

| Figure | GIXRD angle (degrees) | Probed Depth (nm) |
|---|---|---|
| 6A | 1 | 300 |
| 6B | 1.5 | 465 |
| 6C | 2 | 619 |
| 6D | 2.5 | 774 |
| 6E | 3 | 929 |
| 6F | 3.5 | 1083 |
| 6G | 4 | 1238 |
| 6H | 4.5 | 1392 |
| 6I | n/a | 2000 |

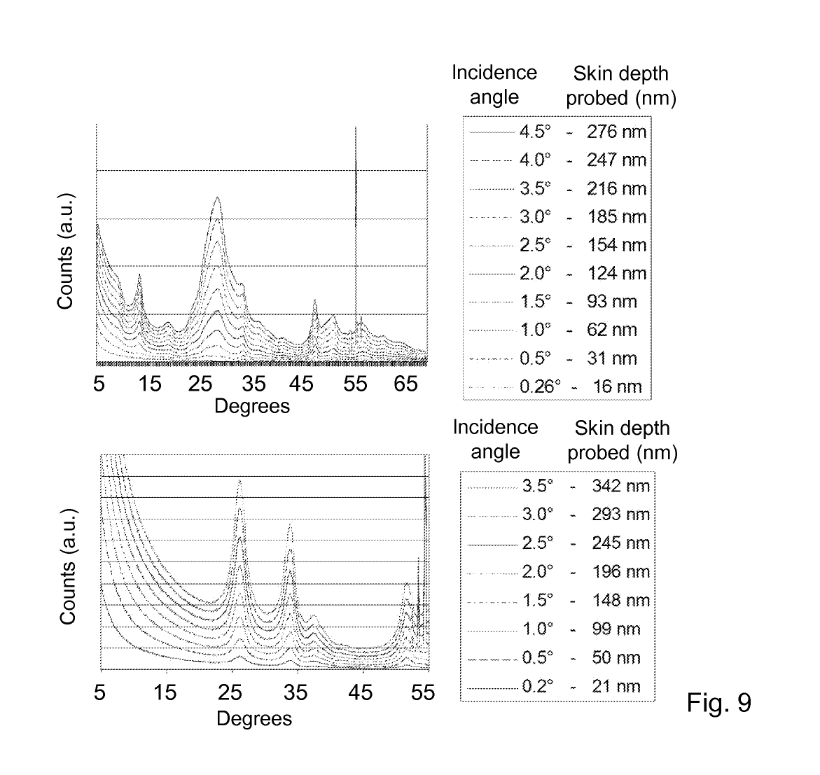

In addition to the hermeticity evaluations conducted using copper oxide-based barrier layers, tin oxide-based barrier layers were also evaluated. As seen with reference to FIG. 9, which shows GIXRD spectra for SnO (top) and SnO₂-deposited films (bottom) after 85/85 exposure, the hermetic thin film (top) exhibits a crystalline SnO₂-like (passivation) layer that has formed over the deposited amorphous SnO layer, while the non-hermetic (SnO₂-deposited) film exhibits an entirely crystalline morphology.

Table 2 highlights the impact of volume change about the central metal ion on the contribution to film stress of the surface hydration products. It has been discovered that a narrow band corresponding to an approximate 15% or less increase in the molar volume change contributes to a hermetically-effective compressive force. In embodiments, a molar volume of the second inorganic layer is from about −1% to 15% (i.e., −1, 0, 1, 2, 3, 4, 5, 6, 7, 8, 9, 10, 11, 12, 13, 14 or 15%) greater than a molar volume of the first inorganic layer. The resulting self-sealing behavior (i.e., hermeticity) appears related to the volume expansion.

TABLE 2
Calculated Molar Volume Change for Various Materials

| Sputtering Target | | Δ Molar | |
|---|---|---|---|
| Material/First | | Volume | Hermetic |
| Inorganic Layer | Second Inorganic Layer | [%] | Layer? |
| SnO | SnO₂ | 5.34 | yes |
| FeO | Fe₂O₃ ^{†} | 27.01 | no |
| Sb₂O₃ (senarmonitite) | Sb₂O₅ ^{†} | 63.10 | no |
| Sb₂O₃ (valentinite) | Sb₂O₅ ^{†} | 67.05 | no |
| Sb₂O₃ (valentinite) | Sb + 3Sb + 5O₄ | −9.61 | no |
| | (cervantite) | | |
| Sb₂O₃ (valentinite) | Sb₃O₆(OH) (stibiconite) ^{†} | −14.80 | no |
| Ti₂O₃ | TiO₂^{†} | 17.76 | no |
| Cu₂O | Cu⁺₂Cu²⁺₂O₃ | 12.30 | no |
| | (paramelaconite) ^{†} | | |
| CuO | Cu⁺₂Cu²⁺₂O₃ | 0.97 | yes |
| | (paramelaconite) | | |

^{†} estimate

Table 3 shows the hermetic-film-forming inorganic oxide was always the least thermodynamically stable oxide, as reflected in its Gibbs free energy of formation, for a given elemental pair. This suggests that as-deposited inorganic oxide films are metastable and thus potentially reactive towards hydrolysis and/or oxidation.

TABLE 3
Gibbs Formation Free Energy (ΔG°_{formation}) of Various Oxides

| Target Material | AG°_{formation} [kJ/mol] | Hermetic Layer |
|---|---|---|
| SnO | −251.9 | yes |
| SnO₂ | −515.8 | no |
| CuO | −129.7 | yes |
| Cu₂O | −146.0 | no |

In embodiments, the barrier layer can be derived from room temperature sputtering of one or more of the foregoing materials, though other thin film deposition techniques can be used. In order to accommodate various workpiece architectures, deposition masks can be used to produce a suitably patterned hermetic barrier layer. Alternatively, conventional lithography and etching techniques can be used to form a patterned hermetic layer from a previously-deposited blanket layer.

To form hermetic barrier layers via sputtering, a sputtering target may comprise a low T_{g} glass material or a precursor thereof, such as a pressed powder target where the powder constituents have an overall composition corresponding to the desired barrier layer composition. Glass-based sputtering targets may comprise a dense, single phase low T_{g} glass material. Aspects of forming both glass composition sputtering targets and pressed powder sputtering targets are disclosed herein.

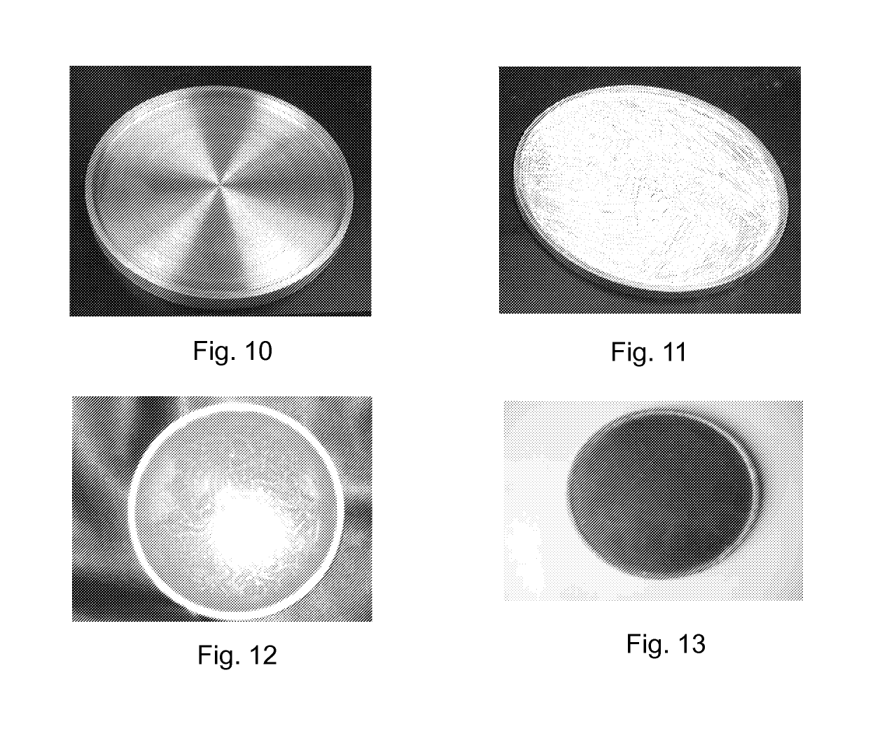

For both glass composition and pressed powder composition targets, a thermally-conductive backing plate such as a copper backing plate may be used to support the target material. The backing plate can have any suitable size and shape. In one example embodiment, a 3 inch outer diameter (OD) circular copper backing plate is formed from a 0.25 inch thick copper plate. A central area having a diameter of about 2.875 inch is milled from the plate to a depth of about ⅛ inch, leaving an approximately 1/16 inch wide lip around a peripheral edge of the central area. A photograph of such a copper backing plate is shown in FIG. 10.

To form a glass composition sputtering target according to one embodiment, the central area of the backing plate is initially coated with a thin layer of flux-less solder (Cerasolzer ECO-155). The solder provides an oxide-free, or substantially oxide-free, adhesion-promoting layer to which the target material can be bonded. An image of a solder-treated copper backing plate is shown in FIG. 11.

A desired glass composition can be prepared from raw starting materials. Starting materials to form a tin fluorophosphate glass, for example, can be mixed and melted to homogenize the glass. The raw materials, which can comprise powder materials, can be heated, for example, in a carbon crucible to a temperature in the range of 500-550° C., and then cast onto a graphite block to form a glass cullet. The cullet can be broken up, remelted (500-550° C.), and then poured into the central area of a pre-heated, solder-treated backing plate. The backing plate can be pre-heated to a temperature in the range of 100-125° C. The casting can be annealed at a temperature of 100-125° C. for 1 hour, though longer anneal times can be used for larger backing plates. An image of an as-annealed low T_{g} glass sputtering target is shown in FIG. 12.

After the glass composition is annealed, the glass can be heat-pressed against the solder-coated copper, e.g., using a Carver press at a temperature of below 225° C., e.g., from 140-225° C. and an applied pressure of 2000-25,000 psi. The heat-pressing promotes thorough compaction and good adhesion of the glass material to the backing plate. In a further embodiment, the step of heat-pressing can be performed at a temperature of less than 180° C. An image of a pressed, low T_{g} glass sputtering target is shown in FIG. 13.

By controlling the temperature and pressure used to anneal and compress the glass target, the formation of unwanted voids or secondary phases can be minimized or avoided. In accordance with various embodiments, a sputtering target comprising a low T_{g} glass material can have a density approaching or equal to the theoretical density of the glass material. Example target materials include glass material having a density greater than 95% of a theoretical density of the material (e.g., at least 96, 97, 98, or 99% dense).

By providing dense sputtering targets, degradation of the target during use can be minimized. For instance, the exposed surface of a target that contains porosity or mixed phases may become preferentially sputtered and roughened during use as the porosity or second phase is exposed. This can result in a runaway degradation of the target surface. A roughened target surface may lead to flaking of particulate material from the target, which can lead to the incorporation of defects or particle occlusions in the deposited layer. A barrier layer comprising such defects may be susceptible to hermetic breakdown. Dense sputtering targets may also exhibit uniform thermal conductivity, which promotes non-destructive heating and cooling of the target material during operation.

According to various embodiments, methods for forming a sputtering target disclosed herein can be used to produce single phase, high density targets of a low T_{g} glass composition. The glass targets can be free of secondary or impurity phases. While the foregoing relates to forming a sputtering target directly on a backing plate, it will be appreciated that a suitable glass-based target composition can be prepared independently from such a backing plate and then optionally incorporated onto a backing plate in a subsequent step.

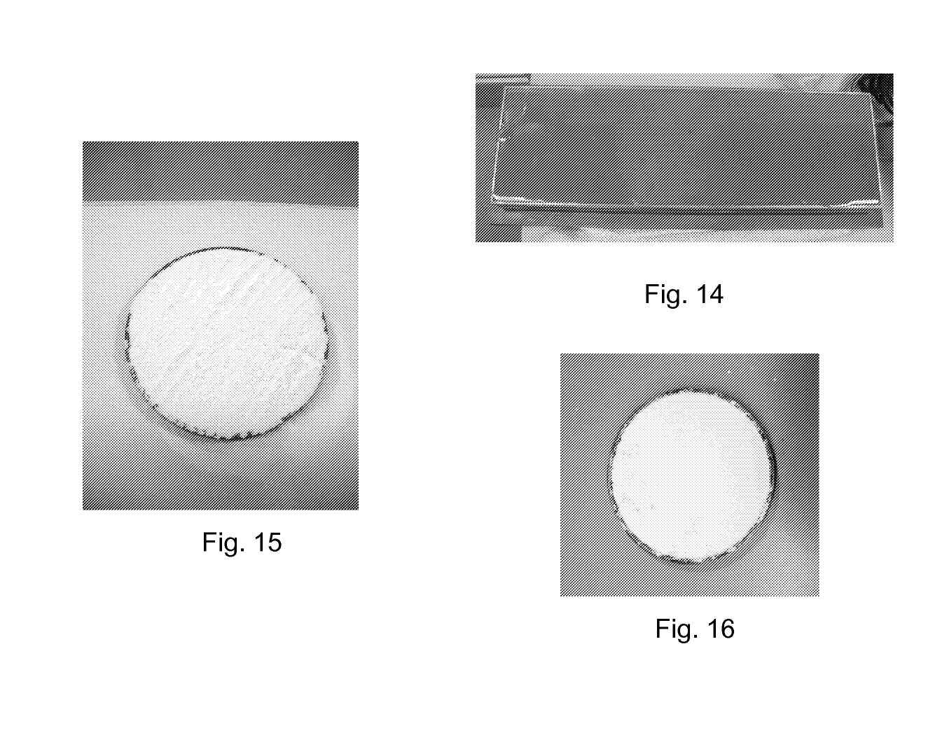

In embodiments, a method of making a sputtering target comprising a low T_{g} glass material comprises providing a mixture of raw material powders, heating the powder mixture to form a molten glass, cooling the glass to form a cullet, melting the cullet to form a glass melt, and shaping the glass melt into a solid sputtering target. FIG. 14 is an image showing the incorporation of glass material into the central area of larger form factor rectangular backing plate.

As an alternative to a glass material-based sputtering target, the steps of melting and homogenizing the starting raw materials can be omitted, and instead powder raw materials can be mixed and pressed directly into the central area of a suitable backing plate. FIG. 15 is an image showing the incorporation of powder raw materials into the central area of a circular backing plate, and FIG. 16 shows a final pressed-powder sputtering target after compression of the powder materials of FIG. 15.

A method of making a pressed-powder sputtering target comprising a powder compact having the composition of a low T_{g} glass comprises providing a mixture of raw material powders, and pressing the mixture into a solid sputtering target. In such an approach, the powder mixture is a precursor of a low T_{g} glass material. In a related approach, a method of making a pressed-powder sputtering target comprising an oxide of copper or tin comprises providing a powder of CuO or SnO and pressing the powder into a solid sputtering target.

Hermetic barrier layers formed by sputtering may be optically transparent, which make them suitable for encapsulating, for example, food items, medical devices, and pharmaceutical materials, where the ability to view the package contents without opening the package may be advantageous. Optical transparency may also be useful in sealing opto-electronic devices such as displays and photovoltaic devices, which rely on light transmission. In embodiments, the hermetic barrier layers have an optical transparency characterized by an optical transmittance of greater than 90% (e.g., greater than 90, 92, 94, 96 or 98%).

In one further example embodiment, sputter-deposited hermetic barrier layers may be used to encapsulate a workpiece that contains a liquid or a gas. Such workpieces include dye-sensitized solar cells (DSSCs), electro-wetting displays, and electrophoretic displays. The disclosed hermetic barrier layers can substantially inhibit exposure of a workpiece to air and/or moisture, which can advantageously prevent undesired physical and/or chemical reactions such as oxidation, hydration, absorption or adsorption, sublimations, etc. as well as the attendant manifestations of such reactions, including spoilage, degradation, swelling, decreased functionality, etc.

Due to the hermeticity of the protective barrier layer, the lifetime of a protected workpiece can be extended beyond that achievable using conventional hermetic barrier layers. Other devices that can be protected using the disclosed materials and methods include organic LEDs, fluorophores, alkali metal electrodes, transparent conducting oxides, and quantum dots.

Disclosed are sputtering targets and methods for forming sputtering targets that comprise a low T_{g} glass material or precursor thereof, or an oxide of copper or tin. Sputtering processes using the foregoing targets can be used to form self-passivating hermetic barrier layers.

As used herein, the singular forms “a,” “an” and “the” include plural referents unless the context clearly dictates otherwise. Thus, for example, reference to a “glass” includes examples having two or more such “glasses” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It is also noted that recitations herein refer to a component being “configured” or “adapted to” function in a particular way. In this respect, such a component is “configured” or “adapted to” embody a particular property, or function in a particular manner, where such recitations are structural recitations as opposed to recitations of intended use. More specifically, the references herein to the manner in which a component is “configured” or “adapted to” denotes an existing physical condition of the component and, as such, is to be taken as a definite recitation of the structural characteristics of the component.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

We claim:

1. A sputtering target comprising a sputtering material selected from the group consisting of a low T_{g} glass, a precursor of a low T_{g} glass, and an oxide of copper or tin.

2. The sputtering target according to claim 1, wherein the sputtering material is formed over a thermally conductive backing plate.

3. The sputtering target according to claim 1, wherein the low T_{g} glass or the low T_{g} glass precursor comprises a material selected from the group consisting of a phosphate glass, a borate glass, a tellurite glass and a chalcogenide glass.

4. The sputtering target according to claim 3, wherein the low T_{g} glass or the low T_{g} glass precursor further comprises a dopant.

5. The sputtering target according to claim 1, wherein the low T_{g} glass or the low T_{g} glass precursor comprises a material selected from the group consisting of a tin phosphate, tin fluorophosphate and a tin fluoroborate.

6. The sputtering target according to claim 1, wherein a composition of the low T_{g} glass or the low T_{g} glass precursor comprises:
20-100 mol % SnO;
0-50 mol % SnF₂; and
0-30 mol % P₂O₅ or B₂O₃.

7. The sputtering target according to claim 1, wherein a composition of the low T_{g} glass or the low T_{g} glass precursor comprises:
35-50 mol % SnO,
30-40 mol % SnF₂,
15-25 mol % P₂O₅ or B₂O₃; and
1.5-3 mol % of at least one dopant oxide selected from the group consisting of WO₃, CeO₂ and Nb₂O₅.

8. The sputtering target according to claim 1, wherein the copper oxide comprises CuO.

9. The sputtering target according to claim 1, wherein the tin oxide comprises SnO.

10. The sputtering target according to claim 1, wherein the copper oxide or tin oxide are amorphous.

11. The sputtering target according to claim 1, wherein the copper oxide or tin oxide are crystalline.

12. The sputtering target according to claim 1, wherein the sputtering material comprises a pressed powder of the copper or tin oxide or the low T_{g} glass precursor.

13. A method of forming a sputtering target comprising a low T_{g} glass material comprising:
providing a mixture of raw material powders;
heating the powder mixture to form a molten low T_{g} glass; and
shaping the glass melt into a solid sputtering target.

14. The method according to claim 13, wherein the shaping comprises pouring the glass melt onto a surface of a backing plate.

15. A method of forming a sputtering target comprising:
providing a mixture of raw material powders, and
pressing the mixture into a solid sputtering target, wherein the powder mixture comprises CuO, SnO or a low T_{g} glass precursor composition selected from the group consisting of a phosphate glass, a borate glass, a tellurite glass, and a chalcogenide glass.
